(19) United States
(12) Patent Application Publication
(10) Pub. No.: US 2018/0041224 A1
(43) Pub. Date: Feb. 8, 2018

(54) DATA VALUE SUFFIX BIT LEVEL COMPRESSION

(71) Applicant: International Business Machines Corporation, Armonk, NY (US)

(72) Inventor: Uttam Setty, Bangalore (IN)

(21) Appl. No.: 15/228,006

(22) Filed: Aug. 4, 2016

(51) Int. Cl. H03M 7/30; G06F 17/30

(52) U.S. Cl. CPC H03M 7/6011; G06F 17/30339; G06F 17/30371

(57) ABSTRACT

One or more data values from a database table in a database are determined. Each data value of the one or more data values are split into one or more individual sections when the one or more data values include two or more characters. The splitting of each data value of the one or more data values results in each section of the one or more individual sections being a single character. Each section of the one or more individual sections is converted into one or more equivalent binary data values. “N” bits of prefix data in the one or more equivalent binary data values are ignored to create one or more common suffixes in the one or more equivalent binary data values. The one or more common suffixes are encoded.

### BACKGROUND

The present invention relates generally to the field of data compression, and more particularly to the compression of common suffixes of data values.

A number of compression techniques exist for compressing data values within database tables. The compression techniques include the following steps: analyzing the data values to build compression dictionaries, compressing the data values using the compression dictionaries, and storing the compressed data. A compression dictionary may be thought of as a shorthand version of the original data values. Data compression helps to reduce the overall size of a database and improves the performance of input/output (I/O) intensive workloads because the data is stored in fewer pages in the database.

### SUMMARY OF THE INVENTION

Embodiments of the present invention include a method, computer program product, and system for the compression of common suffixes of data values. In one embodiment, one or more data values from a database table in a database are determined. Each data value of the one or more data values are split into one or more individual sections when the one or more data values include two or more characters. The splitting of each data value of the one or more data values results in each section of the one or more individual sections being a single character. Each section of the one or more individual sections is converted into one or more equivalent binary data values. “N” bits of prefix data in the one or more equivalent binary data values are ignored to create one or more common suffixes in the one or more equivalent binary data values. The one or more common suffixes are encoded.

### BRIEF DESCRIPTION OF THE DRAWINGS

FIG. 1 depicts a functional block diagram of a computing environment, in accordance with an embodiment of the present invention;

FIG. 2 depicts a flowchart of a program for the compression of common suffixes of data values, in accordance with an embodiment of the present invention;

FIG. 3A depicts an example table demonstrating suffix compression, in accordance with an embodiment of the present invention;

FIG. 3B depicts an example data page following suffix compression, in accordance with an embodiment of the present invention; and

FIG. 4 depicts a block diagram of components of the computing environment of FIG. 1, in accordance with an embodiment of the present invention.

### DETAILED DESCRIPTION

Embodiments of the present invention provide for the compression of common suffixes of data values stored to a database table. Current data compression techniques, of which there are many, include the steps of analyzing data, building compression dictionaries based on the analyzed data, compressing the data using the compression dictionaries, and storing the compressed data. Huffman encoding is one such compression technique. With Huffman encoding, frequency histograms are built based on the various data values to be compressed. If too many data values are present and the number of distinct values are too high, there may be a large amount of stress on the memory resources of the computing device building the histograms. Pruning the histograms may minimize the impact of memory constraints but the pruning may negatively affect the compression rates.

Embodiments of the present invention recognize that there may be a method, computer program product, and computer system for the compression of common suffixes of data values stored to a database table. Embodiments of the present invention may ignore the prefix of multiple data values leaving a common suffix for each data value, which may then be compressed. Using the method, computer program product, and computer system may result in needing less memory to store the data histograms used in compressing the data values, better compression rates due to smaller code size, and better use of memory resources during query runtime. Runtime may be defined as the period of time during which a computer program, in this case, a database query, is executing.

The present invention will now be described in detail with reference to the Figures.

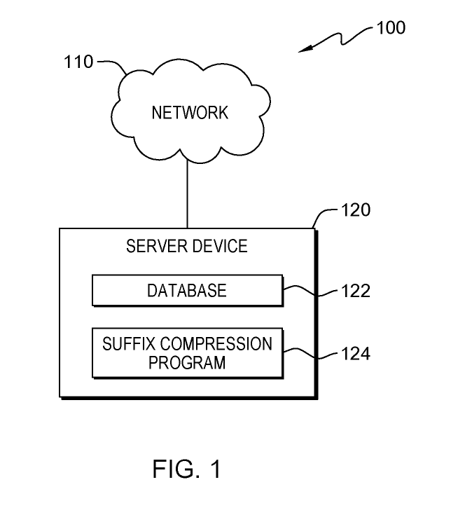

FIG. 1 is a functional block diagram illustrating a computing environment, generally designated 100, in accordance with one embodiment of the present invention. FIG. 1 provides only an illustration of one implementation and does not imply any limitations with regard to the systems and environments in which different embodiments may be implemented. Many modifications to the depicted embodiment may be made by those skilled in the art without departing from the scope of the invention as recited by the claims.

In an embodiment, computing environment 100 includes server device 120 connected to network 110. In example embodiments, computing environment 100 may include other computing devices (not shown) such as smartwatches, cell phones, smartphones, wearable technology, phablets, tablet computers, laptop computers, desktop computers, other computer servers or any other computer system known in the art, interconnected with server device 120 over network 110.

In example embodiments, server device 120 may connect to network 110, which enables server device 120 to access other computing devices and/or data not directly stored on server device 120. Network 110 may be, for example, a local area network (LAN), a telecommunications network, a wide area network (WAN) such as the Internet, or any combination of the three, and include wired, wireless, or fiber optic connections. Network 110 may include one or more wired and/or wireless networks that are capable of receiving and transmitting data, voice, and/or video signals, including multimedia signals that include voice, data, and video information. In general, network 110 can be any combination of connections and protocols that will support communications between server device 120 and any other computing device connected to network 110, in accordance with embodiments of the present invention. In an embodiment, data received by another computing device in computing environment 100 (not shown) may be communicated to server device 120 via network 110.

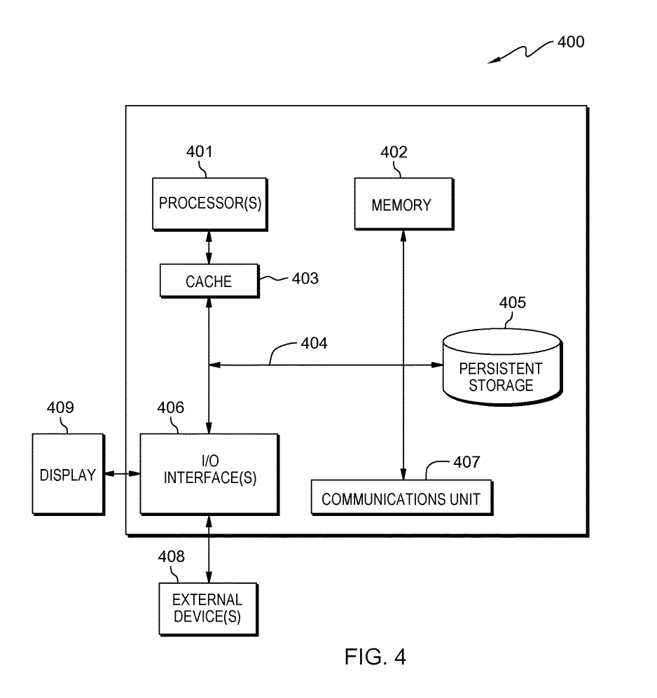

In embodiments of the present invention, server device 120 may be a laptop, tablet, or netbook personal computer (PC), a desktop computer, a personal digital assistant (PDA), a smartphone, a standard cell phone, a smart-watch or any other wearable technology, or any other hand-held, programmable electronic device capable of communicating with any other computing device within computing environment 100. In certain embodiments, server device 120 represents a computer system utilizing clustered computers and components (e.g., database server computers, application server computers, etc.) that act as a single pool of seamless resources when accessed by elements of computing environment 100. In general, server device 120 is representative of any electronic device or combination of electronic devices capable of executing computer readable program instructions. Computing environment 100 may include one server device 120 or any number of server device 120. Server device 120 may include components as depicted and described in further detail with respect to FIG. 4, in accordance with embodiments of the present invention.

In an embodiment, server device 120 includes database 122 and suffix compression program 124. According to embodiments of the present invention, database 122 may be storage that may be written to and/or read by suffix compression program 124. In one embodiment, database 122 resides on server device 120. In other embodiments, database 122 may reside on any other device (not shown) in computing environment 100, in cloud storage or on another computing device accessible via network 110. In yet another embodiment, database 122 may represent multiple storage devices within server device 120. Database 122 may be implemented using any volatile or non-volatile storage media for storing information, as known in the art. For example, database 122 may be implemented with a tape library, optical library, one or more independent hard disk drives, multiple hard disk drives in a redundant array of independent disks (RAID), solid-state drives (SSD), or random access memory (RAM). Similarly, database 122 may be implemented with any suitable storage architecture known in the art, such as a relational database, an object-oriented database, or one or more tables. In an embodiment of the present invention, suffix compression program 124 and any other programs and applications (not shown) operating on server device 120 may store, read, modify, or write data to database 122. Examples of data stored to database 122 include the input data values being loaded into the database tables or the frequency histograms determined by suffix compression program 124.

According to embodiments of the present invention, suffix compression program 124 may be a program, a subprogram of a larger program, an application, a plurality of applications, or mobile application software, which functions to compress common suffixes of data values stored to a database table. A program is a sequence of instructions written by a programmer to perform a specific task. Suffix compression program 124 may run by itself but may be dependent on system software (not shown) to execute. In one embodiment, suffix compression program 124 functions as a stand-alone program residing on server device 120. In another embodiment, suffix compression program 124 may be included as a part of server device 120. In yet another embodiment, suffix compression program 124 may work in conjunction with other programs, applications, etc., found on server device 120 or in computing environment 100. In yet another embodiment, suffix compression program 124 may be found on other computing devices (not shown) in computing environment 100 which are interconnected to server device 120 via network 110.

According to embodiments of the present invention, suffix compression program 124 functions to compress common suffixes of data values. According to an embodiment of the present invention, suffix compression program 124 allows suffixes of data values in a database table to be compressed which may result in needing less memory requirements, better compression rates, and better use of memory during query runtime. In an embodiment, suffix compression program 124 on server device 120 compresses the data values of a table stored to database 122.

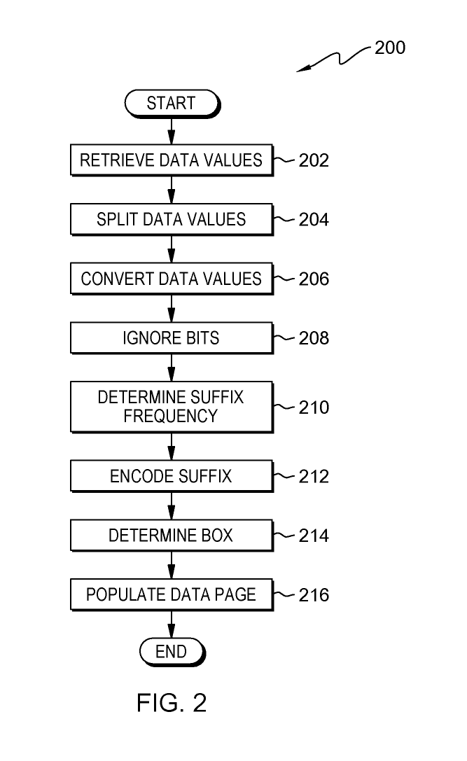

FIG. 2 is a flowchart of workflow 200 depicting a method for the compression of common suffixes of data values, in accordance with an embodiment of the present invention. In one embodiment, the method of workflow 200 is performed by suffix compression program 124. In an alternative embodiment, the method of workflow 200 may be performed by any other program working with suffix compression program 124. In an embodiment, a user, via a user interface (not shown), may invoke workflow 200 upon the user creating a new database table. In another embodiment, workflow 200 may be invoked upon a program initiating a data load into a database table. In an alternative embodiment, a user may invoke workflow 200 upon accessing suffix compression program 124.

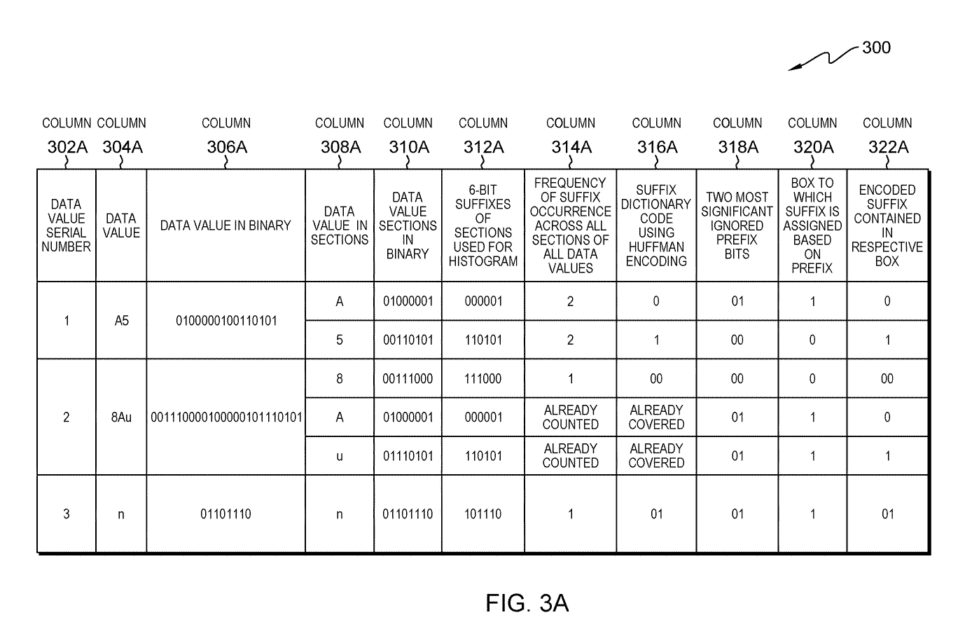

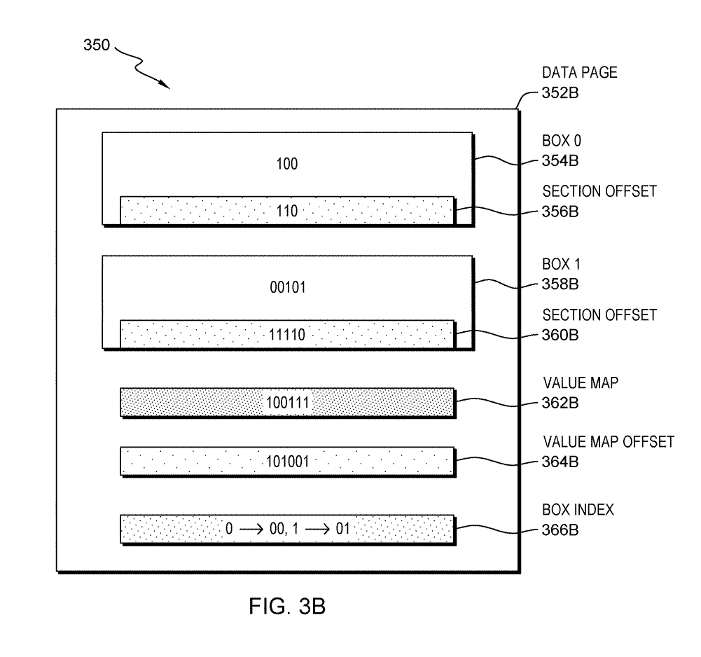

In an embodiment, suffix compression program 124 retrieves data values (step 202). In other words, based on the request of a user or a program, suffix compression program 124 retrieves the data values that require compression from a database table. In an embodiment, suffix compression program 124 retrieves data values from database 122 included on server device 120. For example, the data values “A5” (data value serial number 1 in column 302A), “8Au” (data value serial number 2 in column 302A), and “n” (data value serial number 3 in column 302A), are retrieved from column 304A, as shown in Table 300 in FIG. 3A.

In an embodiment, suffix compression program 124 splits data values (step 204). In other words, suffix compression program 124 splits the data values into individual sections (i.e., single characters) when the data value consists of two or more characters. Splitting the data values into individual sections allows suffix compression program 124 to use any repetitive suffixes of the individual sections and build the frequency histograms of the data values at the individual section level. In an embodiment, suffix compression program 124 splits the data values, where possible, retrieved from database 122 on server device 120. For example, as shown in column 308A in Table 300 in FIG. 3A, the data value “A5” is split into the two sections “A” and “5” and the data value “8Au” is split into the three sections “8”, “A”, and “u”. In some embodiments, data values cannot or do not need to be split. For example, the data value “n” is not split since it is not comprised of multiple characters.

In an embodiment, suffix compression program 124 converts data values (step 206). In other words, suffix compression program 124 converts each split section of the original data values into an equivalent binary data value. Converting the split sections of the original data values to the equivalent binary data values is done to allow suffix compression that may allow for less utilization of memory resources and better utilization of memory resources during query runtime. Runtime is defined as the period of time during which a computer program, in this case, a database query, is executing. In an embodiment, suffix compression program 124 converts the split sections of the original data values to the equivalent binary data value using any of the conversion techniques known in the art. For example, as shown in column 310A in Table 300 in FIG. 3A, section “A” of data value “A5” is converted to binary value “01000001” and section “5” of data value “A5” is converted to binary value “00110101”. Similarly, section “8”, section “A”, and section “u” of data value “8Au” are converted to binary values “00111000”, “01000001”, and “01110101”, respectively. In addition, data value “n” is converted to binary value “01101110”.

In an embodiment, suffix compression program 124 ignores bits (step 208). In other words, suffix compression program 124 ignores “N” bits of prefix data in each of the binary data values to create common suffixes in each of the binary data values where possible. In an embodiment, the value of “N” is defined by the programmer of the database. In another embodiment, the value of “N” is determined by an intelligent system via a sampling of the binary data values stored to a database table (e.g., database 122). In yet another embodiment, the value of “N” is determined by an intelligent system via a sampling of the original data values gathered from the source of the original data values. In an embodiment, suffix compression program 124 ignores “N” bits of prefix data in each of the converted binary data values. For example, as shown in column 312A in Table 300 in FIG. 3A, two bits of prefix data are ignored in each of the converted binary data values (in column 310A) which results in six bit suffix “000001” remaining from “01000001” (section “A”), six bit suffix “110101” remaining from “00110101” (section “5”), six bit suffix “111000” remaining from “00111000” (section “8”), six bit suffix “000001” remaining from “01000001” (section “A”), six bit suffix “110101” from “01110101” (section “u”), and six bit suffix “101110” from “01101110” (data value “n”).

In an embodiment, suffix compression program 124 determines suffix frequency (step 210). In other words, suffix compression program 124 compares each remaining suffix after the “N” prefix bits are ignored to determine the frequency of repeating suffixes (i.e., the number of occurrences of each suffix across all of the sections of all of the data values). In an embodiment, the number of occurrences of each suffix is used to build a histogram that is subsequently used to create the compression dictionary code for each suffix. In an embodiment, suffix compression program 124 determines the frequency of occurrence of each suffix. For example, as shown in column 314A in Table 300 in FIG. 3A, six bit suffix “000001” occurs two times in column 312A, six bit suffix “110101” occurs two times in column 312A, six bit suffix “111000” occurs one time in column 312A, and six bit suffix “101110” occurs one time in column 312A.

In an embodiment, suffix compression program 124 encodes suffix (step 212). In other words, the suffixes created from ignoring “N” bits of data in the original binary data values are encoded to create unique dictionary codes for each unique common suffix. In an embodiment, Huffman encoding is used to encode the suffixes. Huffman encoding is an algorithm used to create a particular type of optimal encoding that is used for lossless data compression. The output from the Huffman algorithm can be viewed as a variable-length code table for encoding a source symbol (such as a data value in a database table). The Huffman algorithm derives the table from the estimated probability or frequency of occurrence for each possible value of the data value. Values that are more common are represented using fewer bits than values that are less common. In another embodiment, any method that uses frequency distribution information of data values may be used to encode the suffixes. In an embodiment, suffix compression program 124 uses Huffman encoding to encode the suffixes of the original data values stored to database 122 in binary form. For example, as shown in column 316A in Table 300 in FIG. 3A, the dictionary code, based on the frequency of occurrence shown in column 314A, is shown for each suffix. The dictionary code for suffix “000001”, which occurs twice, is “0”. The dictionary code for suffix “110101”, which also occurs twice, is “1”. The dictionary code for suffix “111000”, which occurs once, is “00”. The dictionary code for suffix “101110”, which occurs once, is “01”. Since there are four unique values of the suffix values, the suffix values can be depicted optimally by using binary codes that are, at most, two bits. In addition, Huffman encoding dictates that values that occur more frequently can be depicted in fewer bits than values that occur more frequently. Therefore, the two suffixes that occur twice can be depicted by “0” and “1” (fewer bits) while the values that occur only once can be depicted by “00” and “01” (more bits).

In an embodiment, suffix compression program 124 determines the box (step 214). In other words, suffix compression program 124 determines the appropriate box, based on the “N” ignored prefix bits, on the data page to assign the determined dictionary codes. In an embodiment, the box is an area on the data page where specific data is stored. In an embodiment, the number of unique prefix bits across all of the data values in binary format are used to determine the number of boxes required on the data page. In an embodiment, suffix compression program 124 determines the number of unique prefix codes for the data values in the data table. For example, as shown in column 318A in Table 300 in FIG. 3A, there are two unique prefixes (“00” and “01”) for the data values in Table 300. Therefore, only two boxes (box “0” and box “1”, as shown in column 320A in table 300 in FIG. 3A are required. The two boxes are also represented in data page example 350 in FIG. 3B as box 0 354B and box 1 358B found in data page 352B.

In an embodiment, suffix compression program 124 populates the data page (step 216). In other words, suffix compression program 124 populates the data page with the compressed suffix values using the previously determined number of boxes. In an embodiment, the data page is a representation of the physical structure of the memory (e.g., hard disk) where the compressed data values are stored. In an embodiment, the data page may be stored to any storage medium that can be accessed by the database software. In an embodiment, compressed suffix values are stored to one or more boxes in the data page. For example, as shown in data page example 350 in FIG. 3B, compressed suffix value “100” is stored to box 0 354B and compressed suffix value “00101” is stored to box 1 358B.

The following discussion will concern data page example 350 in FIG. 3B. In an embodiment, suffix compression program 124 may determine the following for the data page: the section offset for each box, the value map for the data page, the value map offset, and the box index for the data page.

In an embodiment, the section offset for each box allows a user to read the compressed suffix values of sections stored in each box. Within a given section offset, a value of “1” indicates the start of a compressed suffix value of a section and a value of “0” that precedes another “0” represents continuation in a compressed suffix value of a section and a value of “0” that precedes a “1” ends a compressed suffix value of a section. For example, section offset 356B in box 0 354B in data page 352B includes the information “110” indicating that there are two compressed suffix values in box 0 354B (i.e., the first compressed suffix value is one bit in length as indicated by the “1” in “110” and the second compressed suffix value is two bits in length as indicated by the “10” in “110”). In other words, the first “1” in “110” must indicate a one-bit compressed suffix value since the “1” is not followed by a “0”. The second “1” in “110” is followed by a single “0” (and nothing more) which indicates that the next compressed suffix value is two bits long. The compressed suffix values in box 0 354B are “100” and section offset 356B indicates that the compressed suffix values are one bit long and two bits long. Therefore, the compressed suffix values are “1” and “00”.

For another example, consider box 1 358B, with compressed suffix value “00101”, and section offset 360B, with information “11110”, in data page 352B. Section offset 360B indicates the following: a one bit compressed suffix value, another one bit compressed suffix value, yet another one bit compressed suffix value, and a two bit compressed suffix value. Therefore, the compressed suffix values in box 1 358B are “0”, “0”, “1”, and “01”.

In an embodiment, the value map determines which boxes to read, and in what order, to get ordered sections that make up a data value. In the embodiment, the value map offset determines the length, in bits, of each data value. Used in concert, the value map and the value map offset allow a user to read the data values in the correct order. The example depicted in data page example 350 in FIG. 3B indicates that value map 362B includes the information “100111”. Value map offset 364B, which includes the information “101001”, is comparable to section offset 356B and section offset 360B in that a “1” indicates the start of a value and a “0” that precedes another “0” represents continuation in a data value and a value of “0” that precedes a “1” ends a data value. Therefore, value map offset 364B indicates that the first data value is two bits long, the second data value is three bits long, and the third data value is one bit long. Using the value map information of “100111”, the first data value (which is two bits long) is read from box “1”, then box “0” (the “10” of “100111”). The second data value (which is three bits long) is read from box “0”, then box “1”, and then box “1” (the “011” of “100111”). The third data value (which is one bit long) is read from box “1” (the last “1” of “100111”).

In an embodiment, the box index indicates the prefix for every data value within a box. In addition, the box index is used to stitch the data values back together. As shown in the example depicted in box index 366B in data page example 350 in FIG. 3B, the compressed suffix values within box 0 354B have a prefix of “00” while the compresses suffix values within box 1 358B have a prefix of “01”.

It should be noted that the use of a suffix compression technique such as suffix compression program 124 is compatible with other encoding techniques such as pure dictionary encoding and minus encoding. In addition, suffix encoding may be applied to data values already encoded by other encoding techniques known in the art such as prefix encoding and pure dictionary encoding.

FIG. 4 depicts computer system 400, which is an example of a system that includes suffix compression program 124. Computer system 400 includes processors 401, cache 403, memory 402, persistent storage 405, communications unit 407, input/output (I/O) interface(s) 406 and communications fabric 404. Communications fabric 404 provides communications between cache 403, memory 402, persistent storage 405, communications unit 407, and input/output (I/O) interface(s) 406. Communications fabric 404 can be implemented with any architecture designed for passing data and/or control information between processors (such as microprocessors, communications and network processors, etc.), system memory, peripheral devices, and any other hardware components within a system. For example, communications fabric 404 can be implemented with one or more buses or a crossbar switch.

Memory 402 and persistent storage 405 are computer readable storage media. In this embodiment, memory 402 includes random access memory (RAM). In general, memory 402 can include any suitable volatile or non-volatile computer readable storage media. Cache 403 is a fast memory that enhances the performance of processors 401 by holding recently accessed data, and data near recently accessed data, from memory 402.

Program instructions and data used to practice embodiments of the present invention may be stored in persistent storage 405 and in memory 402 for execution by one or more of the respective processors 401 via cache 403. In an embodiment, persistent storage 405 includes a magnetic hard disk drive. Alternatively, or in addition to a magnetic hard disk drive, persistent storage 405 can include a solid state hard drive, a semiconductor storage device, read-only memory (ROM), erasable programmable read-only memory (EPROM), flash memory, or any other computer readable storage media that is capable of storing program instructions or digital information.

The media used by persistent storage 405 may also be removable. For example, a removable hard drive may be used for persistent storage 405. Other examples include optical and magnetic disks, thumb drives, and smart cards that are inserted into a drive for transfer onto another computer readable storage medium that is also part of persistent storage 405.

Communications unit 407, in these examples, provides for communications with other data processing systems or devices. In these examples, communications unit 407 includes one or more network interface cards. Communications unit 407 may provide communications through the use of either or both physical and wireless communications links. Program instructions and data used to practice embodiments of the present invention may be downloaded to persistent storage 405 through communications unit 407.

I/O interface(s) 406 allows for input and output of data with other devices that may be connected to each computer system. For example, I/O interface 406 may provide a connection to external devices 408 such as a keyboard, keypad, a touch screen, and/or some other suitable input device. External devices 408 can also include portable computer readable storage media such as, for example, thumb drives, portable optical or magnetic disks, and memory cards. Software and data used to practice embodiments of the present invention can be stored on such portable computer readable storage media and can be loaded onto persistent storage 405 via I/O interface(s) 406. I/O interface(s) 406 also connect to display 409.

Display 409 provides a mechanism to display data to a user and may be, for example, a computer monitor.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

What is claimed is:

1. A method for compression of common suffixes of data values, the method comprising:
determining, by one or more computer processors, one or more data values from a database table in a database;
splitting, by one or more computer processors, each data value of the one or more data values into one or more individual sections when the one or more data values include two or more characters, wherein the splitting of each data value of the one or more data values results in each section of the one or more individual sections being a single character;
converting, by one or more computer processors, each section of the one or more individual sections into one or more equivalent binary data values;
ignoring, by one or more computer processors, “N” bits of prefix data in the one or more equivalent binary data values to create one or more common suffixes in the one or more equivalent binary data values; and
encoding, by one or more computer processors, the one or more common suffixes.

2. The method of claim 1, wherein the step of encoding, by one or more computer processors, the one or more common suffixes, comprises;
determining, by one or more computer processors, a frequency of repeating suffixes in the one or more common suffixes; and
encoding, by one or more computer processors, the one or more common suffixes to create a unique dictionary code for each unique common suffix of the one or more common suffixes, wherein frequency distribution information of one or more data values is used to encode the one or more commons suffixes.

3. The method of claim 2, further comprising:
determining, by one or more computer processors, one or more boxes on a data page to assign the unique dictionary codes, wherein the one or more boxes are based on the ignored “N” bits of prefix data; and
populating, by one or more computer processors, the data page with the unique dictionary codes.

4. The method of claim 1, wherein the value of “N” is defined by the group consisting of a user, a sampling of the equivalent binary data values, and a sampling of the one or more data values from the database table in the database.

5. The method of claim 3, wherein the data page includes a section offset for each box of the one or more boxes, a value map, a value map offset, and a box index.

6. The method of claim 5, wherein the section offset allows a user to read the unique dictionary codes, and wherein the value map determines which box of the one or more boxes to read in what order to get ordered sections that make up a data value, and wherein the value map offset determines a length, in bits, of each data value, and wherein the box index indicates a prefix for each data value within the box.

7. The method of claim 1, wherein the method for compression of common suffixes of data values is compatible with other encoding techniques selected from the group consisting of pure dictionary encoding and minus encoding, and wherein the method for compression of common suffixes of data values may be applied to data values already encoded by other encoding techniques selected from the group consisting of prefix encoding and pure dictionary encoding.

8. A computer program product for compression of common suffixes of data values, the computer program product comprising:
one or more computer readable storage media; and
program instructions stored on the one or more computer readable storage media, the program instructions comprising:
program instructions to determine one or more data values from a database table in a database;
program instructions to split each data value of the one or more data values into one or more individual sections when the one or more data values include two or more characters, wherein the splitting of each data value of the one or more data values results in each section of the one or more individual sections being a single character;
program instructions to convert each section of the one or more individual sections into one or more equivalent binary data values;
program instructions to ignore “N” bits of prefix data in the one or more equivalent binary data values to create one or more common suffixes in the one or more equivalent binary data values; and
program instructions to encode the one or more common suffixes.

9. The computer program product of claim 8, wherein the program instructions to encode the one or more common suffixes, comprises:
program instructions to determine a frequency of repeating suffixes in the one or more common suffixes; and
program instructions to encode the one or more common suffixes to create a unique dictionary code for each unique common suffix of the one or more common suffixes, wherein frequency distribution information of one or more data values is used to encode the one or more commons suffixes.

10. The computer program product of claim 9, further comprising program instructions, stored on the one or more computer readable storage media, to:
determine one or more boxes on a data page to assign the unique dictionary codes, wherein the one or more boxes are based on the ignored “N” bits of prefix data; and
populate the data page with the unique dictionary codes.

11. The computer program product of claim 8, wherein the value of “N” is defined by the group consisting of a user, a sampling of the equivalent binary data values, and a sampling of the one or more data values from the database table in the database.

12. The computer program product of claim 10, wherein the data page includes a section offset for each box of the one or more boxes, a value map, a value map offset, and a box index.

13. The computer program product of claim 12, wherein the section offset allows a user to read the unique dictionary codes, and wherein the value map determines which box of the one or more boxes to read in what order to get ordered sections that make up a data value, and wherein the value map offset determines a length, in bits, of each data value, and wherein the box index indicates a prefix for each data value within the box.

14. The computer program product of claim 8, wherein the program instructions for compression of common suffixes of data values is compatible with other encoding techniques selected from the group consisting of pure dictionary encoding and minus encoding, and wherein the program instructions for compression of common suffixes of data values may be applied to data values already encoded by other encoding techniques selected from the group consisting of prefix encoding and pure dictionary encoding.

15. A computer system for compression of common suffixes of data values, the computer system comprising:
one or more computer processors;
one or more computer readable storage media; and
program instructions stored on the one or more computer readable storage media for execution by at least one of the one or more computer processors, the program instructions comprising:
program instructions to determine one or more data values from a database table in a database;
program instructions to split each data value of the one or more data values into one or more individual sections when the one or more data values include two or more characters, wherein the splitting of each data value of the one or more data values results in each section of the one or more individual sections being a single character;
program instructions to convert each section of the one or more individual sections into one or more equivalent binary data values;
program instructions to ignore “N” bits of prefix data in the one or more equivalent binary data values to create one or more common suffixes in the one or more equivalent binary data values; and
program instructions to encode the one or more common suffixes.

16. The computer system of claim 15, wherein the program instructions to encode the one or more common suffixes, comprises:
program instructions to determine a frequency of repeating suffixes in the one or more common suffixes; and
program instructions to encode the one or more common suffixes to create a unique dictionary code for each unique common suffix of the one or more common suffixes, wherein frequency distribution information of one or more data values is used to encode the one or more commons suffixes.

17. The computer system of claim 16, further comprising program instructions stored on the one or more computer readable storage media for execution by at least one of the one or more computer processors, to:
determine one or more boxes on a data page to assign the unique dictionary codes, wherein the one or more boxes are based on the ignored “N” bits of prefix data; and
populate the data page with the unique dictionary codes.

18. The computer system of claim 15, wherein the value of “N” is defined by the group consisting of a user, a sampling of the equivalent binary data values, and a sampling of the one or more data values from the database table in the database.

19. The computer system of claim 17, wherein the data page includes a section offset for each box of the one or more boxes, a value map, a value map offset, and a box index.

20. The computer system of claim 19, wherein the section offset allows a user to read the unique dictionary codes, and wherein the value map determines which box of the one or more boxes to read in what order to get ordered sections that make up a data value, and wherein the value map offset determines a length, in bits, of each data value, and wherein the box index indicates a prefix for each data value within the box.
